(19) United States
(12) Patent Application Publication
(10) Pub. No.: US 2024/0392468 A1
(43) Pub. Date: Nov. 28, 2024

(54) MANUFACTURING CHAMBER INCLUDING QUICK CONNECT FIXTURES

(71) Applicant: Siemens Medical Solutions USA, Inc., Malvern, PA (US)

(72) Inventor: Troy Marlar, Knoxville, TN (US)

(21) Appl. No.: 18/321,169

(22) Filed: May 22, 2023

(51) Int. Cl. C30B 15/14; C30B 15/30

(52) U.S. Cl. CPC C30B 15/14; C30B 15/30

(57) ABSTRACT

A crystal growth station includes a crystal pulling assembly having a rotatable pulling shaft and a furnace chamber having an internal area configured to hold a crystal growth chamber which is configured to receive the rotatable pulling shaft. The furnace chamber includes a cover configured to cover the crystal growth station and heating system configured to heat the internal area. At least one of the cover and the heating system includes at least one quick connect fixture.

### FIELD OF THE INVENTION

The present invention relates generally to crystal growth for nuclear medical imaging, and in particular, to a manufacturing chamber configured to facilitate crystal growth and manufacturing.

### DESCRIPTION OF RELATED ART

The Czochralski crystal growth process (often referred to simply as the “Czochralski method” or “CZ method”) is a widely used process to produce bulk crystals that are used in a wide range of electronic and optical devices. The Czochralski crystal growth process starts with the insertion of a small seed crystal into a melt disposed in a crucible. The crucible is then disposed in a manufacturing chamber typically referred to as “furnace chamber” which heats the crucible as a crystal seed interacts with the melt. The seed is then gradually drawn or “pulled” upwards to form a single crystal boule.

### BRIEF SUMMARY OF THE INVENTION

According to a non-limiting embodiment, a crystal growth station includes a crystal pulling assembly having a rotatable pulling shaft and a furnace chamber having an internal area configured to hold a crystal growth chamber which is configured to receive the rotatable pulling shaft. The furnace chamber includes a cover configured to cover the crystal growth station and heating system configured to heat the internal area. At least one of the cover and the heating system includes at least one quick connect fixture.

According to another non-limiting embodiment, a furnace chamber comprises an internal area configured to hold a crystal growth chamber, a cover, and a heating system. The cover is configured to cover the crystal growth station, and the heating system is configured to heat the internal area. At least one of the cover and the heating system includes at least one quick connect fixture.

### BRIEF DESCRIPTION OF THE DRAWINGS

These and other features, aspects, and advantages of the present invention will become better understood with reference to the following description and appended claims, and accompanying drawings where:

FIG. 1 is a side view of a furnace chamber according to a non-limiting embodiment of the present disclosure;

FIG. 2 is a top view of the furnace chamber shown in FIG. 1; and

FIG. 3 depicts a quick connect fixture assembly according to a non-limiting embodiment of the present disclosure.

### DETAILED DESCRIPTION OF THE INVENTION

The present invention may be understood more readily by reference to the following detailed description of preferred embodiments of the invention as well as to the examples included therein. All numeric values are herein assumed to be modified by the term “about,” whether or not explicitly indicated. The term “about” generally refers to a range of numbers that one of skill in the art would consider equivalent to the recited value (i.e., having the same function or result). In many instances, the term “about” may include numbers that are rounded to the nearest significant figure.

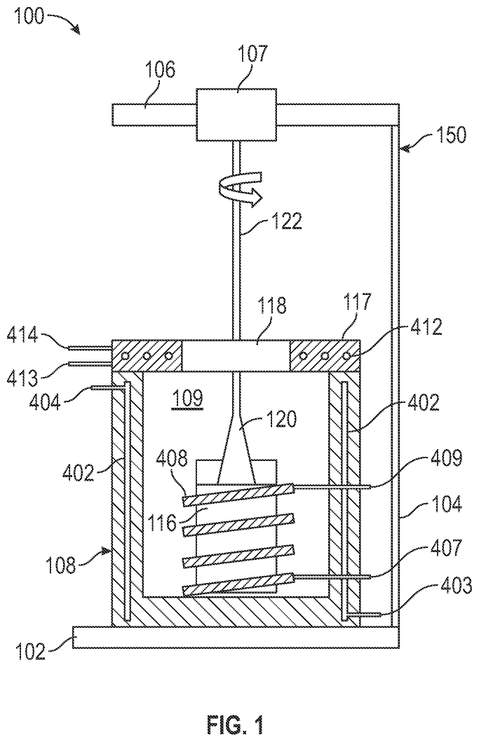

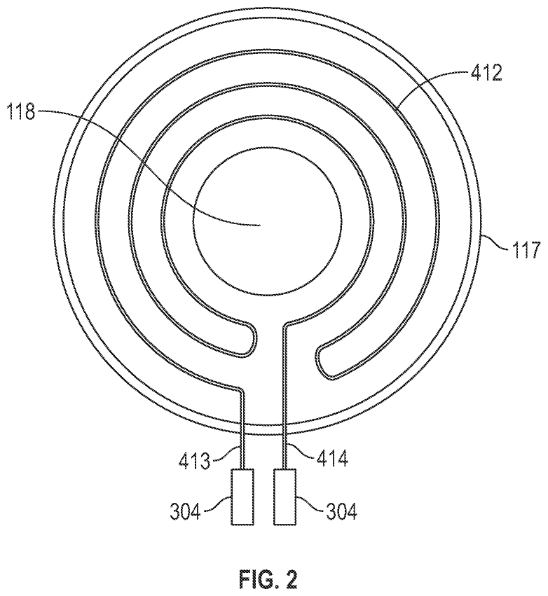

Referring collectively to FIGS. 1 and 2, a crystal growth station 100 is illustrated according to a non-limiting embodiment of the present disclosure. The crystal growth station 100 includes a furnace chamber 108 and a crystal pulling assembly 150. According to a non-limiting embodiment, the furnace chamber 108 is disposed on a fixed platform 102 that is stationary throughout the crystal manufacturing process. The furnace chamber 108 includes an internal area 109 configured to hold a removable crystal growth chamber 116. The crystal growth chamber 116 can house a removable crucible used to hold the raw materials (e.g., powders) used to produce a crystal boule.

The furnace chamber 108 includes a heating system (described in greater detail below), which heats the raw materials (e.g., powders) contained in the crucible and facilitates growth of the crystal boule. Once formation of the crystal boule is completed, the crystal growth chamber 116 is removed from the furnace chamber 108 and the crystal boule is extracted from the crucible.

The furnace heating system includes a variety of fluid conduits and heating coils. According to a non-limiting embodiment, the heating system includes coolant conduits 402 located in the walls of the furnace chamber 108. The coolant conduits 402 supply the furnace chamber 108 with a coolant fluid. The coolant conduits 402 have a coolant inlet port 403 and a coolant exit port 404 through which a coolant fluid enters and exits the furnace chamber 108, respectively. A first external coolant tube (not shown) that supplies the coolant fluid to the conduit 402 may be attached to the coolant inlet port 403 via a first quick connect fixture (e.g., a first coolant quick connect fixture) while a second external coolant tube that transports the coolant fluid away from the coolant conduit 402 may be attached to the coolant exit port 404 via a second quick connect fixture (e.g., a second coolant quick connect fixture). The quick connect fixtures (typically referred to simply as “quick connects”) are described in greater detail below.

The furnace chamber 108 further includes a cover 117 configured to cover the crystal growth chamber and inhibit heat loss from the furnace chamber 108. The cover 117 has a hole 118 formed therethrough, which allows removal of crystal growth chamber 116. The cover 117 contains a circular cover conduit 412 (see FIG. 2 below) which is connected to a cover inlet port 413 and a cover outlet port 414 through which a coolant fluid may enter and exit the cover conduit 412, respectively. A first external cover tube (not shown) that supplies the coolant fluid to the cover conduit 412 may be attached to the cover inlet port 413 via a first cover quick connect 303 (e.g., an inlet cover quick connect) while a second external cover tube (not shown) that transports the cover coolant fluid away from the cover conduit 412 may be attached to the cover exit port 414 via a second cover quick connect 303 (e.g., an outlet cover quick connect). The first and second quick connects 303 are described in greater detail below.

As described herein, the heating system generates heat that heats that internal area 109, and in turn heats the crystal growth chamber 116 to induce melting and reacting of the raw materials (e.g., powders) disposed in the crucible. The heating system includes an induction coil 408 configured to surround the crystal growth chamber 116. The induction coil 408 includes a coil inlet port 407 and a coil outlet port 409. According to a non-limiting embodiment, the induction coil 408 is a hollow metal coil through which a coolant fluid is transported. A first induction coil external tube (not shown) that supplies the coolant fluid to the induction coil 408 may be attached to the coil inlet port 407 via a first coil quick connect fixture while a second induction coil external tube (not shown) that transports the coolant fluid away from the induction coil 408 may be attached to the coil outlet port 409 via a second coil quick connect fixture. The quick connect fixtures are described in greater detail below.

The crystal pulling assembly 150 is configured to promote the growth of a crystal boule in the crystal growth chamber 116. The crystal pulling station 150 includes a pillar 104 and a motion head 106. A first end of the pillar 104 is fixed to a stationary based (e.g. the floor or the fixed platform 102) while the opposing second end is coupled to an end of the motion head 106. The motion head 106 includes a rotatable shaft 122. A first end of the shaft is rotatably coupled to a motor 107 while a crystal seed is coupled to the shaft's opposing end. the seed is placed in contact with the melt and is gradually drawn or “pulled” upwards during rotation of the shaft 122 to form a single crystal boule.

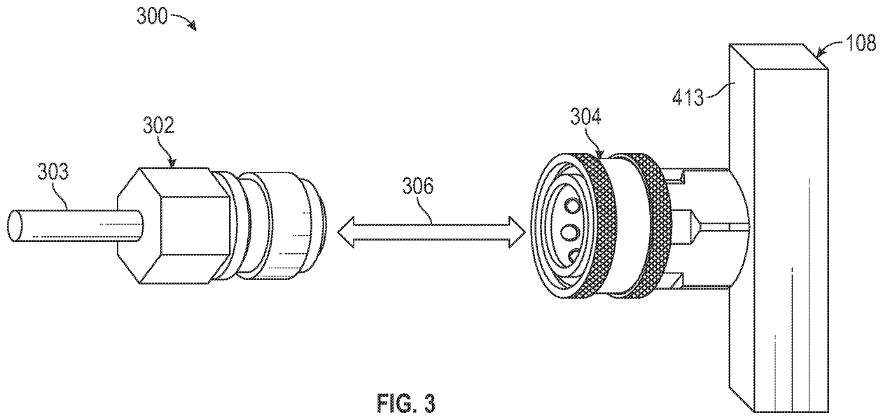

Turning to FIG. 3, a quick connect fixture assembly 300 is illustrated according to a non-limiting embodiment. The quick connect fixture assembly 300 (sometimes referred to as a quick connect coupling assembly) includes a pair of quick connect fixtures, which can be pushed and coupled together, and pulled and decoupled apart (as indicated by arrow 306). Accordingly, the quick connect fixture assembly 300 facilitates a rapid connection and disconnection of the various conduits, tubing and/or coils associated with the furnace chamber 108, the furnace cover 117 (e.g., the cover conduit 412), and/or the heating system (e.g., the induction coil 408). In some instances, the quick connect fixture assembly 300 is referred to as a push-to-connect assembly because connecting the pair of quick connect fixtures requires only a quick push to establish connection or quick pull to break the connection.

The pair of quick connect fixtures includes a male end 302 or “plug” and a female end 304 or “socket”. The male end 302 can be coupled in fluid communication with a conduit or tube, while the female end can be coupled in fluid communication with an inlet or outlet port. The quick connect fixture assembly 300 establishes a secure, leak-tight sealed connection between the conduit/tube and a corresponding inlet/outlet port by inserting the male end 302 into the female end 304. According to the example shown in FIG. 3, the male end can be coupled to an external cover tube 303 that supplies the coolant fluid, while the female end 304 is coupled to the cover inlet port 413. Accordingly, the male end 302 can be pushed into the female end 304 so that coolant fluid may be delivered into the cover conduit 412 (see FIG. 2), and can be pulled apart from the female end 304 to quickly break the connection and stop fluid delivery into the cover conduit 412. Although the cover inlet port 413 is described above, it should be appreciated that a quick connect fixture 304 can be coupled to one or more of the coolant inlet port 403, the coolant exit port 404, the coil inlet port 407, the coil outlet port 409, and the cover outlet port 414 without departing from the scope of the present disclosure.

The quick connect fixture assembly 300 described herein can include, but is not limited to, one-way sleeve designs and two-way sleeve designs. A one-way sleeve design allows for break-away of the connected quick connect fixtures 302 and 304 using a tool when one or more of the quick connect fixtures is clamp mounted. A two-way sleeves design allows for one-hand disconnection of the quick connect fixtures 302 and 304. In two-way designs, twisting and pulling the two quick connect fixtures 302 and 304 can break the connection. In one or more non-limiting embodiments, one or more of the quick connect fixtures 302 and 304 may include a valve to provide an option for starting, stopping or reducing fluid flow.

The quick connect fixtures 302 and 304 can be implemented using various designs without departing from the scope of the present disclosure. For instance, the quick connect fixtures 302 and 304 can include, but are not limited to, a ball bearing coupling design (sometimes referred to as ball-and-sleeve couplings), a flat-face coupling design, a non-latching coupling design, and a Bayonet coupling.

The ball bearing coupling design (e.g., ball-and-sleeve couplings) utilizes spring-loaded balls lodge in cavities to make the connection. The ball bearing coupling design is a type of two-way sleeve design that allows the pair of quick connect fixtures to be disconnected with just one hand.

The flat-face coupling design can be push-to-connect or threaded, screw-in types. Flat face couplings provide high flow and low pressure drop and their sleeve-locking feature reduces the change of accidental connection. Accordingly, the flat-face coupling design can eliminate problems of trapped pressure in a line, as well as leakage of hydraulic fluid or air by eliminating the cavity where the fluid or air rests.

The non-latching coupling design typically includes a self-sealing valve that will hold the fluid in the line to prevent any leakage. Accordingly, non-latching coupling designs are desirable in applications and systems when there may be frequent change-outs of the coupling, such as pneumatic systems used in test or medical applications.

The bayonet coupling design provides an additional locking mechanism (e.g., a slide lock) that maintains the connection in high-pressure applications. For instance, a user pushes together the male end and the female end, and once engaged turns the male end to lock the connection in place. Twisting the male end in the opposite direction unlocks the fixture pair and allows them to be pulled apart.

As described herein, one or more non-limiting embodiments of the present disclosure provides a crystal growth station, which includes a furnace chamber that implements one or more quick connect fixture assemblies. The quick connect fixture assembly facilitates the rapid attachment of the conduits or tubing that supply and remove cooling fluids from the furnace chamber, the furnace cover and/or the furnace heating system.

Although the present invention has been described in considerable detail with reference to certain preferred versions thereof, other versions are possible. Therefore, the spirit and scope of the appended claims should not be limited to the description of the preferred versions contained herein.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means for” performing a specified function, or “step for” performing a specific function, is not to be interpreted as a “means” or “step” clause as specified in 35 U.S.C § 112, sixth paragraph. In particular, the use of “step of” in the claims herein is not intended to invoke the provisions of 35 U.S.C § 112, sixth paragraph.

What is claimed is:

1. A crystal growth station comprising:
a crystal pulling assembly including a rotatable pulling shaft; and
a furnace chamber including an internal area configured to hold a crystal growth chamber which is configured to receive the rotatable pulling shaft, the furnace chamber including:
a cover configured to cover the crystal growth station; and
a heating system configured to heat the internal area;
wherein at least one of the cover and the heating system includes at least one quick connect fixture.

2. The crystal growth station of claim 1, wherein the cover comprises:
a cover conduit including a first cover conduit end configured to receive a coolant fluid and an opposing second cover conduit end configured to expel the coolant fluid;
a cover inlet port coupled to the first cover conduit end; and
a cover outlet port coupled to the second cover conduit end.

3. The crystal growth station of claim 2, wherein the cover further comprises:
an inlet cover quick connect fixture including a first end coupled to the cover inlet port and a second end configured to connect with a first mating quick connect fixture coupled to a first external cover coolant conduit configured to deliver the coolant fluid to the cover inlet port; and
an outlet cover quick connect fixture including a first end coupled to the cover outlet port and a second end configured to connect with a second mating quick connect fixture coupled to a second external cover coolant conduit configured to deliver the coolant fluid away from the cover outlet port.

4. The crystal growth station of claim 2, wherein the heating system comprises:
at least one coolant conduit including a first conduit end configured to receive a coolant fluid and a second conduit end configured to expel the coolant fluid;
a coolant inlet port coupled to the first conduit end; and
a coolant outlet port coupled to the second conduit end.

5. The crystal growth station of claim 4, wherein the heating system further comprises:
an inlet coolant quick connect fixture including a first end coupled to the coolant inlet port and a second end configured to connect with a first mating quick connect fixture coupled to a first external coolant conduit configured to deliver the coolant fluid to the coolant inlet port; and
an outlet coolant quick connect fixture including a first end coupled to the coolant outlet port and a second end configured to connect with a second mating quick connect fixture coupled to a second external coolant conduit configured to deliver the coolant fluid away from the coolant outlet port.

6. The crystal growth station of claim 2, wherein the heating system comprises:
an induction coil including a first coil end configured to receive a coolant fluid and a second coil end configured to expel the coolant fluid;
a coil inlet port coupled to the first coil end; and
a coil outlet port coupled to the second coil end.

7. The crystal growth station of claim 6, wherein the heating system further comprises:
an inlet coil quick connect fixture including a first end coupled to the coil inlet port and a second end configured to connect with a first mating quick connect fixture coupled to a first external coil conduit configured to deliver the coolant fluid to the coil inlet port; and
an outlet coil quick connect fixture including a first end coupled to the coil outlet port and a second end configured to connect with a second mating quick connect fixture coupled to a second external coil conduit configured to deliver the coolant fluid away from the coil outlet port.

8. The crystal growth station of claim 1, wherein the crystal pulling assembly includes a motion head including a motion head motor,
wherein a first end of the rotatable pulling shaft is rotatably coupled to the motion head motor and an opposing second end of the rotatable pulling shaft is configured to be disposed in the furnace chamber.

9. The crystal growth station of claim 1, wherein the at least one quick connect fixture is a first quick connect fixture configured to mate with a second quick connect fixture according to a one-way sleeve design.

10. The crystal growth station of claim 1, wherein the at least one quick connect fixture is a first quick connect fixture configured to mate with a second quick connect fixture according to a two-way sleeve design.

11. A furnace chamber comprising:
an internal area configured to hold a crystal growth chamber:
a cover configured to cover the crystal growth station; and
a heating system configured to heat the internal area;
wherein at least one of the cover and the heating system includes at least one quick connect fixture.

12. The furnace chamber of claim 11, wherein the cover comprises:
a cover conduit including a first cover conduit end configured to receive a coolant fluid and an opposing second cover conduit end configured to expel the coolant fluid;
a cover inlet port coupled to the first cover conduit end; and
a cover outlet port coupled to the second cover conduit end.

13. The furnace chamber of claim 12, wherein the cover further comprises:
an inlet cover quick connect fixture including a first end coupled to the cover inlet port and a second end configured to connect with a first mating quick connect fixture coupled to a first external cover coolant conduit configured to deliver the coolant fluid to the cover inlet port; and
an outlet cover quick connect fixture including a first end coupled to the cover outlet port and a second end configured to connect with a second mating quick connect fixture coupled to a second external cover coolant conduit configured to deliver the coolant fluid away from the cover outlet port.

14. The furnace chamber of claim 12, wherein the heating system comprises:
at least one coolant conduit including a first conduit end configured to receive a coolant fluid and a second conduit end configured to expel the coolant fluid;
a coolant inlet port coupled to the first conduit end; and
a coolant outlet port coupled to the second conduit end.

15. The furnace chamber of claim 14, wherein the heating system further comprises:
an inlet coolant quick connect fixture including a first end coupled to the coolant inlet port and a second end configured to connect with a first mating quick connect fixture coupled to a first external coolant conduit configured to deliver the coolant fluid to the coolant inlet port; and
an outlet coolant quick connect fixture including a first end coupled to the coolant outlet port and a second end configured to connect with a second mating quick connect fixture coupled to a second external coolant conduit configured to deliver the coolant fluid away from the coolant outlet port.

16. The furnace chamber of claim 12, wherein the heating system comprises:
an induction coil including a first coil end configured to receive a coolant fluid and a second coil end configured to expel the coolant fluid;
a coil inlet port coupled to the first coil end; and
a coil outlet port coupled to the second coil end.

17. The furnace chamber of claim 16, wherein the heating system further comprises:
an inlet coil quick connect fixture including a first end coupled to the coil inlet port and a second end configured to connect with a first mating quick connect fixture coupled to a first external coil conduit configured to deliver the coolant fluid to the coil inlet port; and
an outlet coil quick connect fixture including a first end coupled to the coil outlet port and a second end configured to connect with a second mating quick connect fixture coupled to a second external coil conduit configured to deliver the coolant fluid away from the coil outlet port.

18. The furnace chamber of claim 11, wherein the cover includes a hold configured to receive a rotatable pulling shaft.

19. The furnace chamber of claim 11, wherein the at least one quick connect fixture is a first quick connect fixture configured to mate with a second quick connect fixture according to a one-way sleeve design.

20. The furnace chamber of claim 11, wherein the at least one quick connect fixture is a first quick connect fixture configured to mate with a second quick connect fixture according to a two-way sleeve design.
